(19) United States
(12) Patent Application Publication
(10) Pub. No.: US 2024/0235526 A1
(43) Pub. Date: Jul. 11, 2024

(54) NARROW BANDWIDTH SURFACE ACOUSTIC WAVE FILTER

(71) Applicant: Zhejiang Huayuan Micro Electronic Technology Co., Ltd., Huzhou (CN)

(72) Inventors: Serguei N. Kondratiev, Neuchatel (CH); Zhongyun ZHANG, Huzhou (CN); Qian DONG, Huzhou (CN); Zhiyuan ZHANG, Huzhou (CN); Xiaobin CHEN, Huzhou (CN); Xieqian SHEN, Houzhou (CN); Weiyu FENG, Houzhou (CN); Wenhao ZHU, Huzhou (CN); Yangang JIANG, Houzhou (CN)

(73) Assignee: Zhejiang Huayuan Micro Electronic Technology Co., Ltd., Huzhou (CN)

(21) Appl. No.: 18/299,690

(22) Filed: Apr. 12, 2023

(30) Foreign Application Priority Data
Jan. 9, 2023 (CN) 202310027381.1

(51) Int. Cl. H03H 9/64; H03H 9/145

(52) U.S. Cl. CPC H03H 9/6483; H03H 9/145

(57) ABSTRACT

A Surface Acoustic Wave (SAW) Impedance Element Filter (IEF) comprises a cascade of Gamma sections. Each of the Gamma sections comprises a series SAW resonator and a shunt SAW resonator deposited in a surface of a piezoelectric substrate with an additional capacity connected in parallel to the shunt SAW resonator. All the series and shunt SAW resonators have pitches (P) which are substantially equivalent. The SAW IEF has smaller bandwidth to satisfy some specific applications.

### CROSS-REFERENCE TO RELATED APPLICATIONS

This application claims priority to Chinese Patent Application No. 202310027381.1 with a filing date of Jan. 9, 2023. The content of the aforementioned application, including any intervening amendments thereto, is incorporated herein by reference.

### FIELD OF INVENTION

The present disclosure relates to the field of filters, and practically to a narrow bandwidth Surface Acoustic Wave (SAW) filters.

### BACKGROUND TO INVENTION

SAW technology has many different applications in radio electronics and Radio Frequency (RF) art. Due to that fact that SAW velocity is about 100,000 times smaller than that of electromagnetic waves, SAW technology has found special applications where miniaturisation is important or desirable.

As a typical example, Impedance Element (IE) used in Ladder Type of Impedance Element Filters (IEF) contains an Interdigital Transducer (IDT) and two reflecting grating deposited on the surface of piezoelectric substrate. The IDT comprises two sets of metal strips (electrode fingers), which are formed on the surface of a piezoelectric substrate. The electrode fingers in each set are connected by busbars. This arrangement generates SAW in both directions if the voltage is applied to busbars due to piezo-effect. The SAW reflecting gratings contains as usual the periodic system of planar electrodes disposed in an acoustic channel of IDT. Systems electrodes in IDT and gratings are parallel.

It is defined that the relative bandwidth of the IEF is expressed as: ΔF/Fo, where ΔF is the relative difference between Far (high frequency rejection point) and Fr (low frequency rejection point), and Fo is a minimum insertion loss. ΔF/Fo can be reduced a little bit by smaller electrode width but it is in range 3 to 10%.

An objective of the present disclosure is to achieve the smaller bandwidth to satisfy some specific applications.

### SUMMARY OF PRESENT INVENTION

Aiming at the defect in the prior art that the bandwidth of the SAW filter can be further narrowed, the disclosure provided a narrow bandwidth SAW filter.

In order to solve above technical problems, the disclosure provides a SAW IEF, comprising a cascade of Gamma sections, each of the Gamma sections comprises a series SAW resonator and a shunt SAW resonator deposited in a surface of a piezoelectric substrate with an additional capacity connected in parallel to the shunt SAW resonator, all the series and shunt SAW resonators have pitches which are substantially equivalent.

Further, pitches of all series and shunt SAW resonators are equal to each other's.

Further, pitches of all the shunt SAW resonators are smaller than pitches of the series resonators.

Further, a number of Gamma sections is between 2 and 10.

Further, for each of the Gamma sections, a capacity ratio R_{C}=C_{AD}/C_{IE2} is in a range of 2 to 8, wherein C_{AD} is a capacity of the additional capacity, and C_{IE2} is a static capacity of the shunt SAW resonator.

Further, the shunt SAW resonators are connected by adjacent grounds.

Further, the additional capacity is deposited in the surface of the piezoelectric substrate.

Further, the additional capacity is an interdigital transducer (IDT).

Further, the IDT contains two identical IDT sections with an opposite polarity of electrodes, and a gap between the two IDT sections is equal a gap between the electrodes.

Further, the electrodes of the IDT are perpendicular to electrodes of the series and shunt SAW resonators.

Further, the electrodes of the IDT are rotated on an angle of 30 to 90 degrees related to the electrodes of the series and shunt SAW resonators.

Further, the IDT is integrated in a busbar and functions as connection electrodes of the SAW IEF.

Further, a series capacity (Cint) is deposited in the surface of the piezoelectric substrate between each two adjacent Gamma sections instead of between two series SAW resonators.

Further, the series capacity contains two identical IDT sections with an opposite polarity of electrodes.

Further, the series capacity contains sections connected in parallel, and a number of the sections connected in parallel is between two and ten.

Further, a capacity of the series capacity is substantially equivalent to a static capacity of the series SAW resonators.

Further, the series SAW resonators with a frequency of anti-resonance at a request rejection frequency is deposited in the surface of the piezoelectric substrate.

The advantages of the disclosure are as follows: the SAW filter has a narrow bandwidth, better frequency performance and better rejection performance.

### BRIEF DESCRIPTION OF DRAWINGS

FIG. 1 shows an equivalent scheme of a Gamma section according to an embodiment of the disclosure;

FIG. 2 shows a schematic drawing of an IEF with four Gamma sections;

FIG. 3 shows an equivalent scheme of the IEF with four Gamma sections;

FIG. 4 shows the simulation (in solid lines) and measurements (in dashed lines) of frequency response of the IEF shown in FIG. 3;

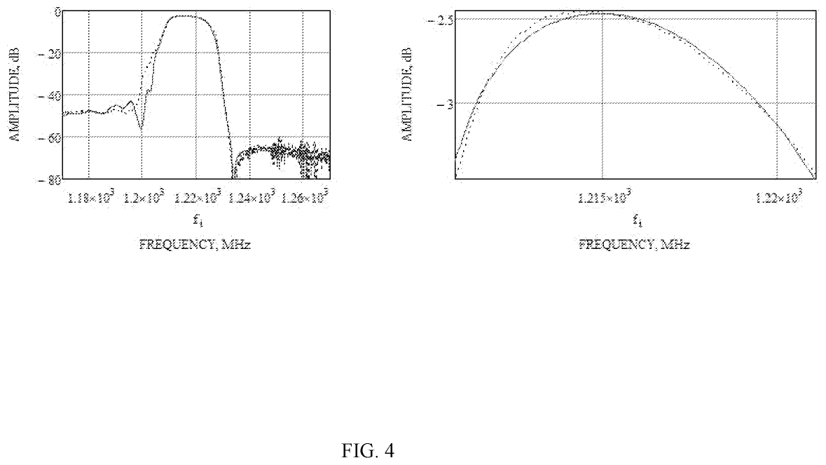

FIG. 5 shows an equivalent scheme of an IEF with four Gamma sections with resonator IE1 in series;

FIG. 6 shows the simulation (in solid lines) and measurements (in dashed lines) of frequency response of the IEF shown in FIG. 5;

FIG. 7 shows a frequency response simulation result of a narrow band IEF with a pitch of shunt SAW resonator IE2 (p2=1672 nm) smaller than a pitch of series SAW resonator IE1 (p1=1673 nm);

FIG. 8 shows a schematic drawing of the IEF shown in FIG. 5;

FIG. 9 shows an equivalent scheme of an IEF according to an embodiment of the disclosure;

FIG. 10 shows a schematic drawing of the IEF shown in FIG. 9;

FIG. 11 shows a frequency response simulation result of the IEF shown in FIG. 9;

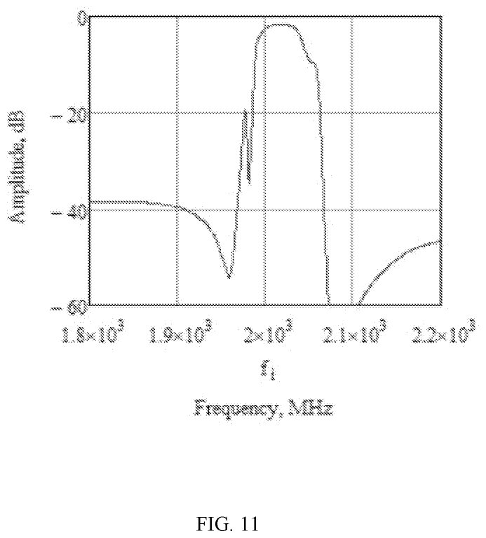

FIG. 12 shows a schematic drawing of a SAW IEF with a series capacity according an embodiment of the disclosure; and

FIG. 13 shows a frequency response of the IEF with a frequency of anti-resonance at 2120 MHz.

### DETAILED DESCRIPTION OF PREFERRED EMBODIMENTS

In order to make the objects, technical solution and advantages of the present disclosure more clear, the present disclosure will be further described in detail with reference to the accompanying drawings and embodiments below. It should be understood that embodiments described here are only for explaining the present disclosure and the disclosure, however, should not be constructed as limited to the embodiment as set forth herein.

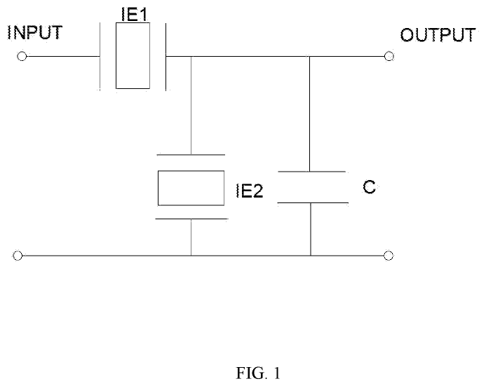

According to the present invention there is provided to use a cascade of Gamma sections of series resonators shunt resonators deposited in a surface of piezoelectric substrate. FIG. 1 shows an equivalent scheme of a Gamma section according to an embodiment of the disclosure. Each of the Gamma section comprises a series SAW resonator IE1 and a shunt SAW resonator IE2 deposited in a surface of a piezoelectric substrate with an additional capacity C connected in parallel to the shunt SAW resonator IE2. All the series and shunt SAW resonators have pitches p which are substantially equivalent. The series SAW resonator IE1 is in series to an input. The shunt SAW resonator IE2 is in parallel to an output. The additional capacity C is connected to parallel to the shunt SAW resonator IE2 and the output.

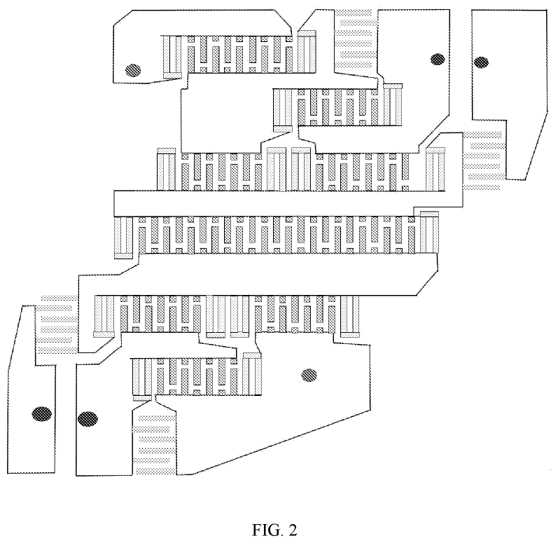

FIG. 2 shows a schematic drawing of an IEF with four Gamma sections. As shown in FIG. 2, all busbars connected to the ground terminal are isolated on the die surface.

According to this embodiment, the main idea and difference between the IEF of the disclosure and the conventional IEF is that pitches p of all the series and shunt SAW resonators are substantially equivalent.

The number N of Gamma sections of the IEF is in range 2 to 10. If N=1, there is a significant degradation of the frequency performance. In case N>10, the filter has to occupy bigger area, the power consumption is too much high and is impractical.

In each of the Gamma sections, a capacity ratio R_{C}=C_{AD}/C_{IE2} is in a range of 2 to 8, C_{AD} is a capacity of the additional capacity C, and C_{IE2} is a static capacity of the shunt SAW resonator. If the capacity ratio is out this range, there is a significant degradation in the frequency performance of the filter.

The second difference between the IEF of the disclosure and the conventional IEF is that all pitches of the shunt and series SAW resonators are equal each other's.

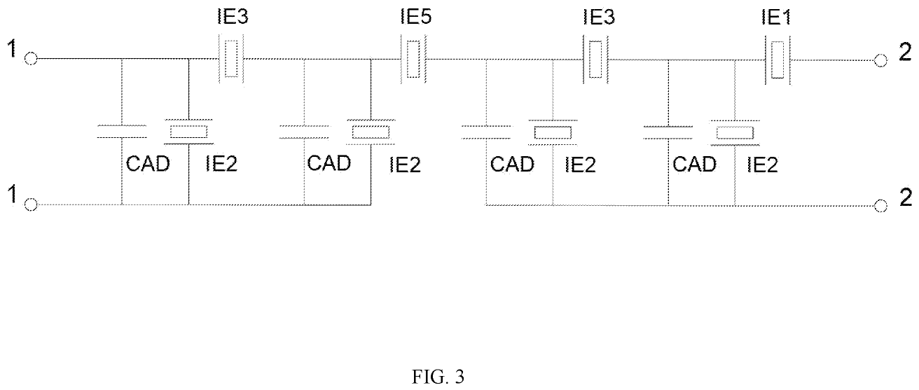

The FIG. 3 shows an equivalent scheme of a 1220 MHz IEF with four Gamma sections. In the equivalent scheme, the shunt SAW resonators IE2 are connected to two adjacent “common grounds”, wherein any one of the shunt SAW resonators is only connected to one of the common grounds. The shunt SAW resonators IE2 shown in FIG. 3 are connected to four isolated grounds, which is different from the structure shown in FIG. 2. This ground connection demonstrates better rejection at 1.15 GHz than compared with the structure shown in FIG. 2.

In the IEF shown in FIG. 3, Pitches of the shunt SAW resonator IE2 and the series SAW resonators IE1, IE3, IE5 are equal to 1673 nm.

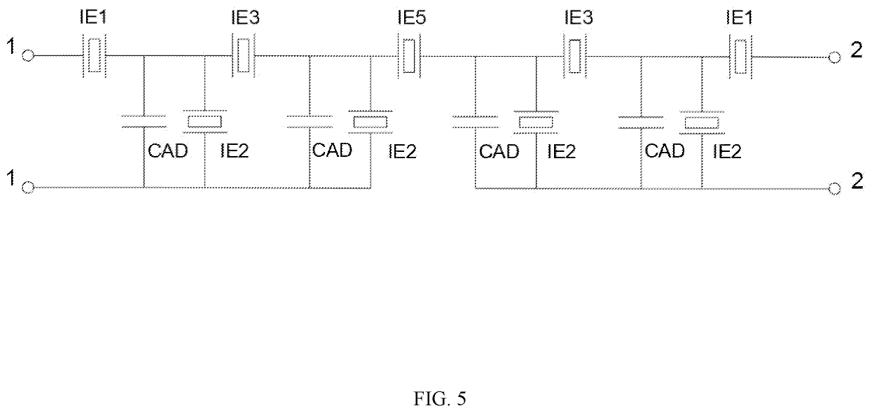

FIG. 5 shows an equivalent scheme of an IEF with four Gamma sections. Compared with the IEF shown in FIG. 3, a series SAW resonator IE1 is added to an input 1. The significant improvement in bandwidth can be achieved by adding the resonator IE1. The pitch is 1659 nm as in other resonators.

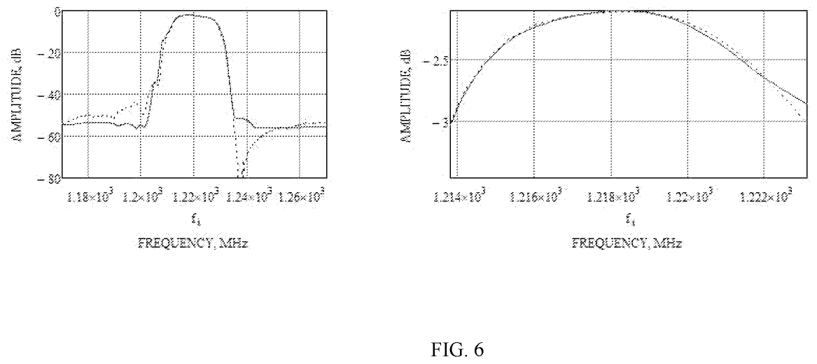

FIG. 6 shows the simulation (in solid lines) and measurements (in dashed lines) of frequency response of four Gamma sections with the resonator IE1 in series.

The advantage of the scheme shown in FIG. 5 is in the symmetric input and output. The capacity ratio of a 1220 MHz IEF is R_{C}=3.1 dB band is about 11 MHz; and 30 dB band is equal to 26 MHz. It is more than twice smaller than that of the conventional IEF:

The bandwidth can be smaller if the number of the Gamma sections is 6 or 8 and the capacity ratio is more than 3.

The reason of narrower band operational is that the frequency shift between resonance and anti-resonance frequency is a few times smaller than that in the conventional IEF by the additional capacity which is connected in parallel to the shunt SAW resonators IE2. This additional capacity has an influence on resonance frequencies (resonance and anti-resonance) of the series SAW resonators IE1.

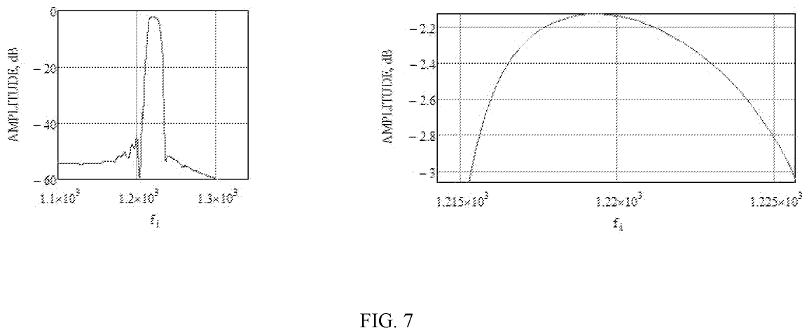

According to embodiments of the disclosure, pitches of all the shunt SAW resonators IE2 are smaller than pitches of the series resonators IE1. FIG. 7 shows the simulation of the narrow band IEF with the pitch of shunt SAW resonators IE2 (p2=1672 nm) smaller than the pitch of the series SAW resonators IE1 (p1=1673 nm). The 1 dB band is a little bit smaller than that of the IEF shown in FIG. 3 where the pitches are identical.

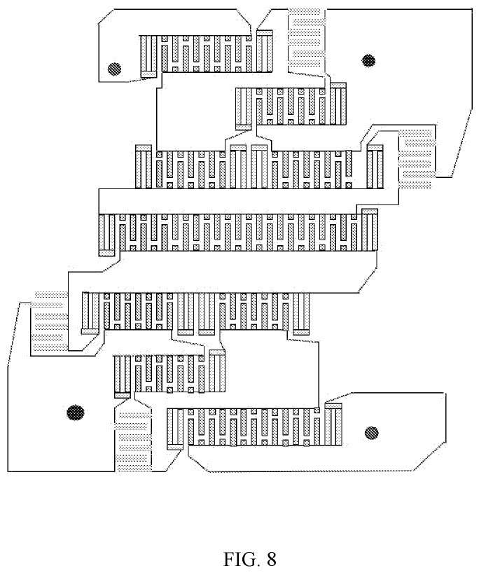

FIG. 8 shows a schematic drawing of the IEF shown in FIG. 5. There are four shunt SAW resonators IE2, a first and second shunt SAW resonators have a first “common” ground which is connected to the input terminal; and a third and fourth shunt SAW resonators have a second “common” ground which is connected to the output terminal.

All additional capacities are integrated in the busbar and function as connection electrodes of the SAW IEF. It is of prime importance to minimize the die size.

In the prior art, the IDT can be used as an additional capacity parallel to the shunt SAW resonator IE2. The disadvantage of this structure of IDT is in radiation of spurious modes (SAW and Bulk Acoustic Waves (BAW)). The most efficient method to minimize level of excitation of spurious modes is in cascade of two identical sections of IDT with an opposite polarity of electrodes as in FIG. 8. A gap between the IDT sections is equal to a gap between IDT electrodes. In this case, the maximum amplitude of the frequency response is twice smaller than that of the standard IDT in prior art. If the gap between partial IDTs is equal to its length, this amplitude is four times smaller.

The level of excitation of spurious modes can be minimized by using the optimal angle of rotation in a range of 30 to 90 degrees of the electrodes of the additional capacity relative to the electrodes of the series and shunt SAW resonators. The optimal rotation angle depends on the crystal and the crystal cut.

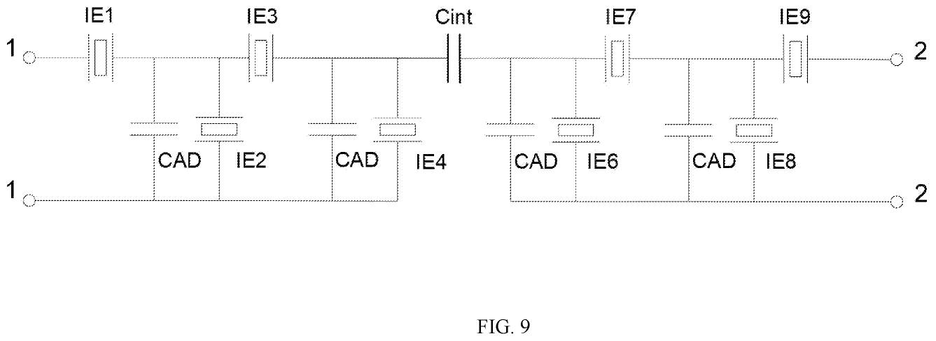

FIG. 9 shows an equivalent scheme of an IEF according to an embodiment of the disclosure. The IEF comprises four Gamma sections. The first Gamma section comprises the series SAW resonator IE1, the shunt SAW resonator IE2 and the additional capacity C_{AD}. The second Gamma section comprises the series SAW resonator IE3, the shunt SAW resonator IE4 and the additional capacity C_{AD}. The third Gamma section comprises the series SAW resonator IE7, the shunt SAW resonator IE6 and the additional capacity C_{AD}. The fourth Gamma section comprises the series SAW resonator IE9, the shunt SAW resonator IE8 and the additional capacity C_{AD}. The four Gamma sections are divided into two groups, the first group comprises the first and second Gamma sections, and the second group comprises the third and fourth Gamma sections. A series capacity Cint is connected between the first and second groups.

The simulation shows that the significant improvement of the SAW filter performance is in case when the additional capacity in series is deposited in the surface of piezoelectric substrate between the first and second groups instead of between the series SAW resonators.

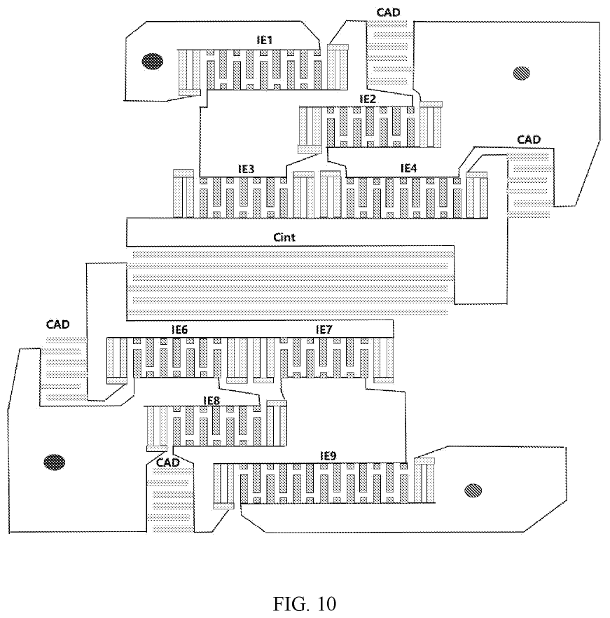

FIG. 10 shows a frequency response of the SAW IEF shown in FIG. 9. The simulation shows that the frequency performance of the IEF is improved significantly.

In an embodiment of the disclosure, to minimize level of excitation of spurious modes, a cascade of two identical sections of IDT with an opposite polarity of electrodes is shown in FIG. 8. The gap between two IDT sections is equal to the gap between the additional capacity electrodes of the shunt SAW resonators.

The additional capacity Cint may be integrated in the busbar and connection electrodes to minimize the die size of IEF.

To minimize the electrode resistance as well as the IEF insertion loss, the additional capacity Cint may contain N sections connected in parallel. In this case, the additional capacity Cint electrode resistance is N*N times smaller than that of single IDT as shown in FIG. 10.

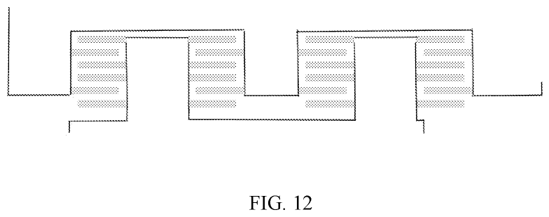

The FIG. 12 shows a geometry of the additional capacity Cint with four sections. In embodiments of the disclosure, the number of sections of the additional capacity Cint is between 2 and 10.

In an embodiment, the series SAW resonator with the frequency of anti-resonance at the request rejection frequency is deposited in the surface of piezoelectric substrate between two groups, which realizes the performance with better rejection in the request frequency range.

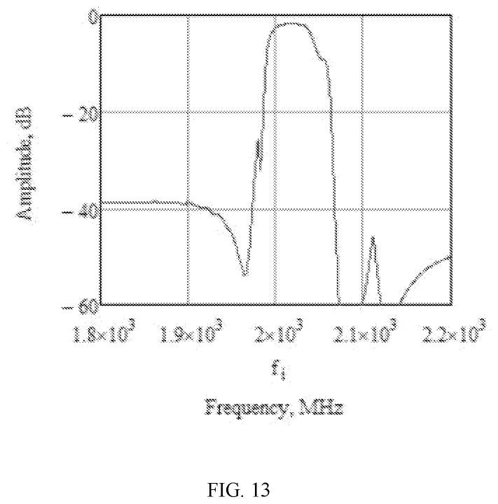

FIG. 13 shows the frequency response of the IEF with the series SAW resonator connected between two groups of the IEF with the frequency of anti-resonance at 2120 MHz.

The scope of the present disclosure includes any novel feature or combination of features disclosed therein either explicitly or implicitly or any generalisation thereof irrespective of whether or not it relates to the claimed invention or mitigates any or all of the problems addressed by the present invention. The applicant hereby gives notice that new claims may be formulated to such features during prosecution of this application or any such further application derived therefrom.

What is claimed is:

1. A Surface Acoustic Wave (SAW) Impedance Element Filter (IEF), comprising a cascade of Gamma sections, wherein each of the Gamma sections comprises a series SAW resonator and a shunt SAW resonator deposited in a surface of a piezoelectric substrate with an additional capacity connected in parallel to the shunt SAW resonator, all the series and shunt SAW resonators have pitches (P) which are substantially equivalent.

2. The SAW IEF according to claim 1, wherein pitches of all series and shunt SAW resonators are equal to each other's.

3. The SAW IEF according to claim 1, wherein pitches of all the shunt SAW resonators are smaller than pitches of the series resonators.

4. The SAW IEF according to claim 1, wherein a number of Gamma sections is between 2 and 10.

5. The SAW IEF according to claim 1, wherein for each of the Gamma sections, a capacity ratio R_{C}=C_{AD}/C_{IE2} is in a range of 2 to 8, wherein C_{AD} is a capacity of the additional capacity, and C_{IE2} is a static capacity of the shunt SAW resonator.

6. The SAW IEF according to claim 1, wherein the shunt SAW resonators are connected by adjacent grounds.

7. The SAW IEF according to claim 1, wherein the additional capacity is deposited in the surface of the piezoelectric substrate.

8. The SAW IEF according to claim 7, wherein the additional capacity is an interdigital transducer (IDT).

9. The SAW IEF according to claim 8, wherein the IDT contains two identical IDT sections with an opposite polarity of electrodes, and a gap between the two IDT sections is equal a gap between the electrodes.

10. The SAW IEF according to claim 8, wherein the electrodes of the IDT are perpendicular to electrodes of the series and shunt SAW resonators.

11. The SAW IEF according to claim 10, wherein the electrodes of the IDT are rotated on an angle of 30 to 90 degrees related to the electrodes of the series and shunt SAW resonators.

12. The SAW IEF according to claim 8, wherein the IDT is integrated in a busbar and functions as connection electrodes of the SAW IEF.

13. The SAW IEF according to claim 1, wherein a series capacity (Cint) is deposited in the surface of the piezoelectric substrate between each two adjacent Gamma sections instead of between two series SAW resonators.

14. The SAW IEF according to claim 13, wherein the series capacity contains two identical IDT sections with an opposite polarity of electrodes.

15. The SAW IEF according to claim 13, wherein the series capacity contains sections connected in parallel, and a number of the sections connected in parallel is between two and ten.

16. The SAW IEF according to claim 13, wherein a capacity of the series capacity is substantially equivalent to a static capacity of the series SAW resonators.

17. The SAW IEF according to claim 1, wherein the series SAW resonators with a frequency of anti-resonance at a request rejection frequency is deposited in the surface of the piezoelectric substrate.
